(19) United States
(12) Patent Application Publication
(10) Pub. No.: US 2014/0003012 A1
(43) Pub. Date: Jan. 2, 2014

(54) CAPACITOR-EMBEDDED PRINTED CIRCUIT BOARD

(71) Applicant: SAMSUNG ELECTRO-MECHANICS CO., LTD., Suwon (KR)

(72) Inventors: Doo Hwan LEE, Suwon (KR); Jong In Ryu, Suwon (KR); Dae Hyun Park, Suwon (KR); Han Kim, Suwon (KR)

(73) Assignee: SAMSUNG ELECTRO-MECHANICS CO., LTD., Suwon (KR)

(21) Appl. No.: 13/800,760

(22) Filed: Mar. 13, 2013

(30) Foreign Application Priority Data
Jul. 2, 2012 (KR) 10-2012-0071875

(51) Int. Cl. H05K 1/18

(52) U.S. Cl. CPC H05K 1/182
USPC 361/763

(57) ABSTRACT

Disclosed herein is a capacitor-embedded printed circuit board, including first to fourth layers forming a four-layer laminated structure; and one or more capacitors embedded through the second layer and the third layer among the first to fourth layers, wherein the respective capacitors embedded through the second layer and the third layer are electrically connected to one or more power terminals of active elements and ground terminals, and wherein at the second or third layer, power terminal wirings are connected to thereby allow the capacitors to form a mutual parallel connection structure, and thus, in embedding capacitors in a laminated structured board having a plurality of layers, a capacitor-embedded printed circuit board capable of reducing the impedance in the entire frequency region and having a high capacitance and a low equivalent series inductance can be realized by effectively connecting capacitors embedded inside the printed circuit board in parallel with each other.

### CROSS REFERENCE(S) TO RELATED APPLICATIONS

This application claims the benefit under 35 U.S.C. Section 119 of Korean Patent Application Serial No. 10-2012-0071875, entitled “Capacitor-Embedded Printed Circuit Board” filed on Jul. 2, 2012, which is hereby incorporated by reference in its entirety into this application.

### BACKGROUND OF THE INVENTION

1. Technical Field

The present invention relates to a capacitor-embedded printed circuit board, and more particularly, to a capacitor-embedded printed circuit board capable of optimizing the performance of a component such as a microprocessor used in a portable device or the like, by effectively connecting capacitors embedded in a board in parallel with each other.

2. Description of the Related Art

Generally, a microprocessor has capacitors which are connected to a circuit in order to improve the power supply stability according to the increase in operating frequency. In this matter, as a way to miniaturize a portable device or the like and realize the maximum performance thereof, a technology of embedding capacitors in a substrate has been used. However, the technology for a component-embedded substrate up to now has not yet reached a satisfactory level in view of optimum arrangement of capacitors for obtaining the best performance or the like.

In embedding the capacitors in the board, when comparing a direct connection of the capacitors to a power terminal with a parallel connection of the capacitors, in the case of the parallel connection, the overall capacitance value corresponds to a simple sum of capacitance values of respective capacitors, and the equivalent series inductance value is proportional to a sum of reciprocals of the capacitance values of the respective capacitors. However, in most cases, the space available is not enough to connect limitless capacitors in parallel, and thus, in order to realize the optimum performance, a parallel connection method of capacitors is necessary to obtain the maximum effect within a given space.

U.S. Pat. No. 7,613,007 discloses the technology where capacitors are embedded in the board.

According to the related art, as disclosed in the above US Patent, sheet type or chip type capacitors are connected in parallel or in series by using an appropriately connected circuit (an unspecific circuit shared by layers) while being embedded in the board. However, in this case, it is difficult to separately limit a circuit connected to a region excluding the capacitors, and thus a designer should think about an interconnection without a standardized type all the time.

### RELATED ART DOCUMENTS

### Patent Document

(Patent Document 1) U.S. Pat. No. 7,613,007

(Patent Document 2) Korean Patent Laid-Open Publication No. 10-2006-098771

### SUMMARY OF THE INVENTION

An object of the present invention is to provide a capacitor-embedded printed circuit board, capable of optimizing the performance of a part such as a microprocessor used in a portable device or the like, by effectively connecting capacitors embedded in a board in parallel with each other.

According to one exemplary embodiment of the present invention, there is provided a capacitor-embedded printed circuit board, including: first to fourth layers forming a four-layer laminated structure; and one or more capacitors embedded through the second layer and the third layer among the first to fourth layers, wherein the respective capacitors embedded through the second layer and the third layer are electrically connected to one or more power terminals of active elements and ground terminals, and wherein at the second or third layer, power terminal wirings are connected to thereby allow the capacitors to form a mutual parallel connection structure.

Here, at the third layer, the power terminal wirings may be connected.

Here, at the second or third layer, conductive lines connected with a ground (GND) may be connected.

According to another exemplary embodiment of the present invention, there is provided a capacitor-embedded printed circuit board, including: first to sixth layers forming a six-layer laminated structure; and one or more capacitors embedded through the third layer and the fourth layer among the first to sixth layers, wherein the respective capacitors embedded through the third layer and the fourth layer are electrically connected to one or more power terminals of active elements and ground terminals, and wherein at the second or fifth layer, power terminal wirings are connected to thereby allow the capacitors to form a mutual parallel connection structure.

Here, at the second or fifth layer, conductive lines connected with a ground (GND) may be connected.

According to still another exemplary embodiment of the present invention, there is provided a capacitor-embedded printed circuit board, including: first to fourth layers forming a four-layer laminated structure; and one or more capacitor-embedded through the second layer and the third layer among the first to fourth layers, wherein the respective capacitors embedded through the second layer and the third layer are electrically connected to one or more power terminals of active elements and ground terminals, and wherein at the layers disposed at the left side or right side of the capacitors, power terminal wirings are connected to thereby allow the capacitors to form a mutual parallel connection structure.

Here, at the layers disposed at the left side or right side of the capacitors, conductive lines connected with a ground (GND) may be connected.

### BRIEF DESCRIPTION OF THE DRAWINGS

FIG. 1 is a view showing an internal constitution of a capacitor-embedded printed circuit board according to a first exemplary embodiment of the present invention;

FIG. 2 is a view showing a connection relationship between embedded capacitors and conductive lines of each layer in the capacitor-embedded printed circuit board of FIG. 1;

FIG. 3 is an equivalent circuit view showing a structure where the internal capacitors are connected in parallel by power connection in the capacitor-embedded printed circuit board of FIG. 1;

FIG. 4 is a view schematically showing a constitution of a capacitor-embedded printed circuit board according to a second exemplary embodiment of the present invention;

FIG. 5 is a view schematically showing a constitution of a capacitor-embedded printed circuit board according to a third exemplary embodiment of the present invention; and

FIG. 6 is a view showing simulation results of impedance characteristics over frequency by using a capacitor-embedded printed circuit board according to the present invention.

### DESCRIPTION OF THE PREFERRED EMBODIMENTS

Terms and words used in the present specification and claims are not to be construed as a general or dictionary meaning but are to be construed to have meaning and concepts meeting the technical ideas of the present invention based on a principle that the inventors can appropriately define the concepts of terms in order to describe their own inventions in best mode.

Through the specification, unless explicitly described to the contrary, the word “comprise” and variations such as “comprises” or “comprising”, will be understood to imply the inclusion of stated elements but not the exclusion of any other elements. In addition, the terms “-er”, “-or”, “module”, and “unit” described in the specification mean units for processing at least one function and operation, and can be implemented by hardware components or software components and combinations thereof.

Exemplary embodiments of the present invention will now be described in detail with reference to the accompanying drawings.

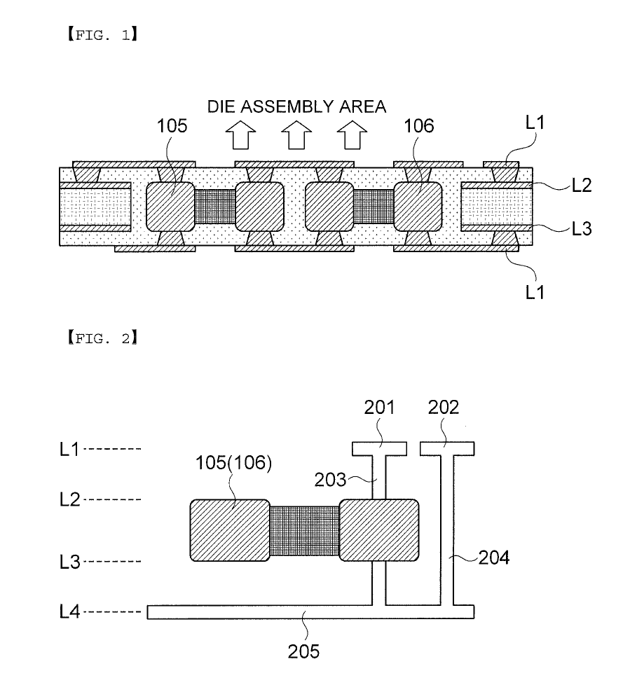

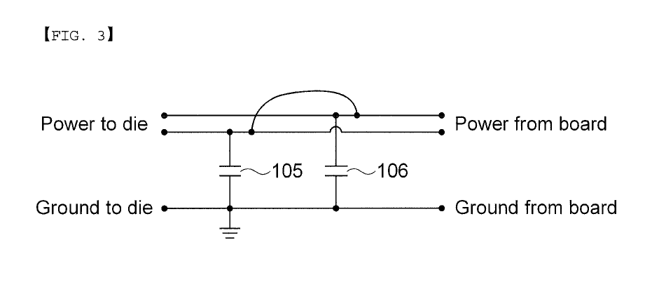

FIGS. 1 and 2 show a capacitor-embedded printed circuit board according to a first exemplary embodiment of the present invention. FIG. 1 is a view showing an internal constitution of the printed circuit board; and FIG. 2 is a view showing a connection relationship between embedded capacitors and conductive lines of each layer.

Referring to FIGS. 1 and 2, a capacitor-embedded printed circuit board according to a first exemplary embodiment of the present invention may include first to fourth layers L1˜L4 forming a four-layer laminated structure; and one or more capacitors 105 and 106 embedded in the second layer L2 and the third layer L3 among the first to fourth layers L1˜L4.

Here, in particular, the capacitors 105 and 106 embedded in the second layer L2 and the third layer L3 are electrically connected to one or more power supply parts 201 and 202 of active elements, respectively, and to a ground terminal. At the second layer L2 or the third layer L3, power terminal wirings 203 and 204 are connected with each other, and thus, as shown in FIG. 3, the capacitors 105 and 106 form a mutual parallel connection structure.

Here, preferably, at the third layer L3, the power terminal wirings 203 and 204 connected with the power supply parts 201 and 202 are connected with each other. Reference numeral 205 denotes a conductive line.

In addition, conductive lines connected with the ground GND (see, FIG. 3) may be connected with each other at the second layer L2 or the third layer L3.

As described above, the first and second power supply parts 201 and 202 are connected with each other at the third layer L3, but may be also connected with each other at the fourth layer L4. With respect to a die, the most effective wiring connection may be performed at the second or third layer since power is supplied through capacitors. Like a second exemplary embodiment to be described below, in the case where chips (capacitors) are embedded in cores of third and fourth layers in a six-layer laminated structure, it is favorable to integrate the capacitors in parallel at the second, third, fourth, fifth, and sixth layers L2, L3, L4, L5, and L6, and the resultant effect may be L2>L3>L4>L5>L6. However, like the four-layer structure of the first exemplary embodiment as described above, the connection of power terminals at the bottom (a combined portion with a main board) has a possibility of influencing power performance even slightly, and thus, it is preferable to realize the power connection at the embedded layers (for example, second and third layers in the four-layer structure, or second, third, fourth, and fifth layer in the six-layer structure).

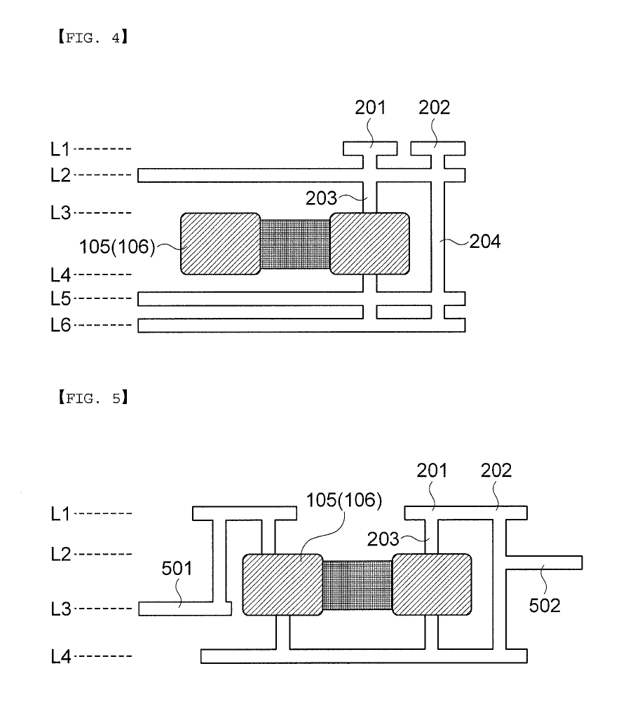

FIG. 4 is a view schematically showing a constitution of a capacitor-embedded printed circuit board according to a second exemplary embodiment of the present invention.

Referring to FIG. 4, a capacitor-embedded printed circuit board according to a second exemplary embodiment of the present invention may include first to sixth layers L1˜L6 forming a six-layer laminated structure; and one or more capacitors 105 and 106 embedded in the third layer L3 and the fourth layer L4 among the first to sixth layers L1˜L6.

Here, in particular, the respective capacitors 105 and 106 embedded in the third layer L3 and the fourth layer L4 are electrically connected to one or more power supply parts 201 and 202 of active elements and ground terminals. At the second layer L2 or the fifth layer L5, power terminal wirings 203 and 204 are connected with each other, and thus, the capacitors 105 and 106 may form a mutual parallel connection structure.

Here, conductive lines connected with the ground GND may be connected with each other at the second layer L2 or the fifth layer L5.

In the forgoing structure according to the second exemplary embodiment of the present invention, the power and the ground are connected with the capacitors directly below a die, resulting in parallel connection of the capacitors, and thus, the second layer L2 and the fifth layer L5 may be utilized as a charge source (well).

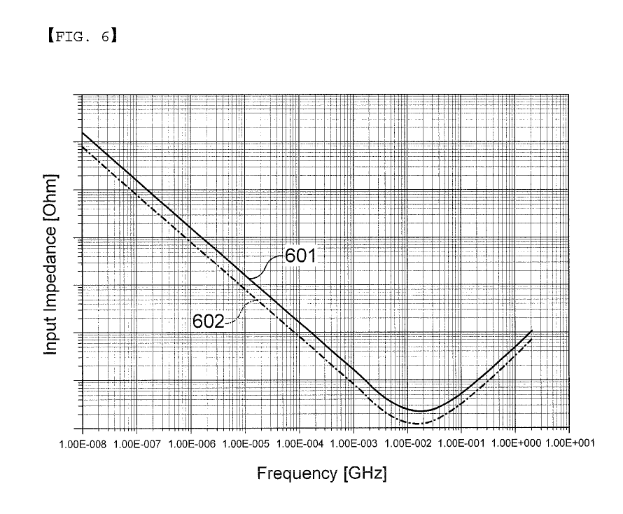

FIG. 5 is a view schematically showing a constitution of a capacitor-embedded printed circuit board according to a third exemplary embodiment of the present invention.

Referring to FIG. 5, a capacitor-embedded printed circuit board according to a third exemplary embodiment of the present invention may include first to fourth layers L1˜L4 forming a four-layer laminated structure; and one or more capacitors 105 and 106 embedded in the second layer L2 and the third layer L3 among the first to fourth layers L1˜L4.

Here, the respective capacitors 105 and 106 embedded in the second layer L2 and the third layer L3 are electrically connected to one or more power supply parts 201 and 202 of active elements and ground terminals. At the layers 501 and 502 disposed at the left side and right side of the capacitors 105 and 106, power terminal wirings are connected with each other, and thus, the capacitors 105 and 106 form a mutual parallel connection structure (see, FIG. 3).

In addition, here, conductive lines connected with the ground GND may be connected with each other at the layers 501 and 502 disposed at the left side and right side of the capacitors 105 and 106.

FIG. 6 is a view showing simulation results of impedance characteristics for frequencies by using the capacitor-embedded printed circuit board according to the present invention, which has the above constitution.

As shown in FIG. 6, it can be seen that the impedance can be reduced in all the frequency regions by the parallel interconnection of the first and second powers (602) as indicated in this document than a case where the first and second powers are separated from each other (601). On a characteristic graph, based on an inflection point, the left side of the inflection point represents a case where the capacitance is higher than the separated case, and the right side of the inflection point represents a case where the inductance is lower than the separated case.

As described above, according to the present invention, in respect to embedding capacitors inside a laminated structure board having a plurality of layers, a capacitor-embedded printed circuit board capable of reducing the impedance in the entire frequency region and having a high capacitance and a low equivalent series inductance can be realized by effectively connecting capacitors embedded in the board in parallel with each other.

The capacitor-embedded printed circuit boards having a four-layer structure and a six-layer structure are mainly described as above, but the capacitor-embedded printed circuit board according to the present invention is not limited to the four-layer structure or the six-layer structure. Printed circuit boards may have various layers such as three layers, five layers, or one of seven to ten layers.

In addition, in boards having various layer structures, capacitors may be connected at regions where the capacitors are embedded, except for the uppermost layer to which active elements are connected, and at all of the other layers.

That is, a capacitor-embedded printed circuit board according to another exemplary embodiment (fourth exemplary embodiment) of the present invention includes a plurality of layers forming a laminated structure; and one or more capacitors embedded in the rest of the layers except for the uppermost layer to which active elements are connected, among the plurality of layers. The capacitors embedded in the reset layers except for the uppermost layer are electrically connected to one or more power terminals and a ground terminal. At the rest of the layers except for the uppermost layer, the power terminal wirings are connected with each other and thus the capacitors form a mutual parallel connection structure.

As set forth above, according to the present invention, in embedding capacitors in a laminated structured board having a plurality of layers, a capacitor-embedded printed circuit board capable of reducing the impedance in the entire frequency region and having a high capacitance and a low equivalent series inductance can be realized by effectively connecting capacitors embedded inside the printed circuit board in parallel with each other.

Although the exemplary embodiments of the present invention have been disclosed for illustrative purposes, the present invention is not limited thereto, and it will be appreciated to those skilled in the art that various modifications, additions and substitutions are possible, without departing from the scope and spirit of the invention as disclosed in the accompanying claims. Therefore, the protection scope of the present invention must be construed by the following claims and it should be construed that all spirit within a scope equivalent thereto are included in the scope of the present invention.

What is claimed is:

1. A capacitor-embedded printed circuit board, comprising:
first to fourth layers forming a four-layer laminated structure; and
one or more capacitors embedded through the second layer and the third layer among the first to fourth layers,
wherein the respective capacitors embedded through the second layer and the third layer are electrically connected to one or more power terminals of active elements and ground terminals, and wherein at the second or third layer, power terminal wirings are connected to thereby allow the capacitors to form a mutual parallel connection structure.

2. The capacitor-embedded printed circuit board according to claim 1, wherein at the third layer, the power terminal wirings are connected.

3. The capacitor-embedded printed circuit board according to claim 1, wherein at the second or third layer, conductive lines connected with a ground (GND) are connected.

4. The capacitor-embedded printed circuit board according to claim 2, wherein at the second or third layer, conductive lines connected with a ground (GND) are connected.

5. A capacitor-embedded printed circuit board, comprising:
first to sixth layers forming a six-layer laminated structure; and
one or more capacitors embedded through the third layer and the fourth layer among the first to sixth layers,
wherein the respective capacitors embedded through the third layer and the fourth layer are electrically connected to one or more power terminals of active elements and ground terminals, and wherein at the second or fifth layer, power terminal wirings are connected to thereby allow the capacitors to form a mutual parallel connection structure.

6. The capacitor-embedded printed circuit board according to claim 5, wherein at the second or fifth layer, conductive lines connected with a ground (GND) are connected.

7. A capacitor-embedded printed circuit board, comprising:
first to fourth layers forming a four-layer laminated structure; and
one or more capacitor-embedded through the second layer and the third layer among the first to fourth layers,
wherein the respective capacitors embedded through the second layer and the third layer are electrically connected to one or more power terminals of active elements and ground terminals, and wherein at the layers disposed at the left side or right side of the capacitors, power terminal wirings are connected to thereby allow the capacitors to form a mutual parallel connection structure.

8. The capacitor-embedded printed circuit board according to claim 7, wherein at the layers disposed at the left side or right side of the capacitors, conductive lines connected with a ground (GND) are connected.

9. A capacitor-embedded printed circuit board, comprising:
a plurality of layers forming a laminated structure; and
one or more capacitors embedded in the rest of the layers except for the uppermost layer to which active elements are connected, among the plurality of layers,
wherein the respective capacitors embedded in the reset layers except for the uppermost layer are electrically connected to one or more power terminals of active elements and ground terminals, and wherein at the rest of the layers except for the uppermost layer, power terminal wirings are connected to thereby allow the capacitors to form a mutual parallel connection structure.
